(19) United States
(12) Patent Application Publication
(10) Pub. No.: US 2020/0260605 A1
(43) Pub. Date: Aug. 13, 2020

(54) MOBILE TERMINAL

(71) Applicant: LG ELECTRONICS INC., Seoul (KR)

(72) Inventors: Minjong LEE, Seoul (KR); Sunggyu KOH, Seoul (KR); Younghee CHO, Seoul (KR); Jongkyu JU, Seoul (KR)

(73) Assignee: LG ELECTRONICS INC., Seoul (KR)

(21) Appl. No.: 16/651,670

(22) PCT Filed: Sep. 5, 2018
(86) PCT No.: PCT/KR2018/010346

§ 371 Date: Mar. 27, 2020

(30) Foreign Application Priority Data
Sep. 29, 2017 (KR) 10-2017-0127377

(51) Int. Cl. H05K 5/04; H05K 5/00; H04B 1/3827; B29C 45/14

(52) U.S. Cl. CPC H05K 5/04; H05K 5/0017; H04M 1/0266; H04B 1/3827; B29C 45/14508; H05K 5/0004

(57) ABSTRACT

There is disclosed a mobile terminal comprising a display unit; a metal plate configured to support a rear surface of the display unit; a middle case arranged around the metal plate and comprising a connecting portion projected from an inner surface and connected with the metal plate; a molding portion injection-molded between an inner surface of the middle case and the metal plate; and a rear case coupled to a rear surface of the middle case and configured to define an exterior of the rear surface, wherein the middle case is formed of an amorphous metal having higher strength and rigidity than a metal of the metal plate, so that the middle case is made of amorphous metal to be resistant to scratch and the inner plate connected with the middle frame is made of a different material from the outer case so as to solve the disadvantage of the conventional frame made of one metal.

### FIELD

Embodiments of the present disclosure relate to a mobile terminal which includes an outer case exposed outside which is made of amorphous metal to be resistant to scratch and an inner plate connected with the outer case which is made of a different material from the outer case so as to solve a disadvantage of a conventional frame made of one metal.

### BACKGROUND

Terminals may be generally classified as mobile/portable terminals or stationary terminals according to their mobility. Mobile terminals may also be classified as handheld terminals or vehicle mounted terminals according to whether or not a user can directly carry the terminal.

Mobile terminals have become increasingly more functional. Examples of such functions include data and voice communications, capturing images and video via a camera, recording audio, playing music files via a speaker system, and displaying images and video on a display. Some mobile terminals include additional functionality which supports game playing, while other terminals are configured as multimedia players. More recently, mobile terminals have been configured to receive broadcast and multicast signals which permit viewing of content such as videos and television programs.

As such functions become more diversified, the mobile terminal can support more complicated functions such as capturing images or video, reproducing music or video files, playing games, receiving broadcast signals, and the like. By comprehensively and collectively implementing such functions, the mobile terminal may be embodied in the form of a multimedia player or device.

By extension, as the functions become expanded, the mobile terminal becomes one of necessary personal belongings and the exterior design then becomes an important factor in determining consumers' product preference. Accordingly, there are increasing needs for the improvement of the exterior design.

Especially, needs for designs using the metal capable of improving the design and product intensity are increasing. It is difficult to process such the metal and the metal requires additional cost, so that research and development on a metal case are actively ongoing.

There are also ongoing studies and researches on a method for manufacturing a case which uses an amorphous metal having high strength and rigidity so as to improve the design and product strength.

### DETAILED DESCRIPTION OF THE INVENTION

### Technical Problem

Accordingly, an object of the present invention is to address the above-noted and other problems and provide a mobile terminal which may the disadvantage of the frame made of one metal by making an outer case exposed outside of amorphous metal to be resistant to scratch and an inner plate connected with the outer case of a different material from the outer case.

### Technical Solution

Embodiments of the present disclosure may provide a mobile terminal comprising a display unit; a metal plate configured to support a rear surface of the display unit; a middle case arranged around the metal plate and comprising a connecting portion projected from an inner surface and connected with the metal plate; a molding portion injection-molded between an inner surface of the middle case and the metal plate; and a rear case coupled to a rear surface of the middle case and configured to define an exterior of the rear surface, wherein the middle case is formed of an amorphous metal having higher strength and rigidity than a metal of the metal plate.

The metal plate may be formed of a metal having a higher heat transfer coefficient and a lower electric resistance than the metal of the middle case.

The metal plate may be formed of aluminum or magnesium.

The mobile terminal may further comprise a wireless communication unit configured to supply an electric power to the middle case and implement RF communication, wherein the plurality of the connecting portion are arranged at preset intervals in the inner surface of the middle case and the distance between the connecting portions is different from the wavelength of a signal used in the RF communication.

The signal used in the RF communication may be 700 MHz˜900 MHz or 1700 MHz˜2100 MHz, and the connecting portions may be arranged along the middle case at intervals of 20 mm˜24 mm.

The connecting portion may be connected with the metal plate via a rivet.

The connecting portion may comprise an inclined area extended from the inner surface of the middle case and inclined toward the display unit; and a fastening area extended from one end of the inclined area, in parallel with the metal plate, and connected with the metal plate via the rivet.

The metal plate may comprise a groove provided in an edge and configured to receive the fastening area, and a hole may be formed in one of the fastening area and the groove and a rivet projection may be provided in the other one to be inserted in the hole.

The metal plate may comprise a rivet projection projected from the edge backwardly and configured to be inserted in the hole formed in the fastening area.

An edge of the display unit may be bent backwardly to contact with a front surface of the middle case, and the molding portion may be configured to contact with an edge of a rear surface of the display unit, while surrounding the connecting portions.

An edge of the rear case may be bent forwardly to contact with a rear surface of the middle case and the molding portion may be configured to contact with an edge of a rear surface of the rear case, while surrounding the connecting portions.

### Advantageous Effects

According to the embodiments of the present disclosure, the mobile terminal has following effects.

The mobile terminal is capable of realizing the polished exterior with a high scratch-resistance by using the amorphous metal frame. Accordingly, the mobile terminal may secure the design competitive power.

Furthermore, the outer frame exposed outside is formed of the amorphous metal and the inner frame connected with the outer frame is formed of the different metal. Accordingly, the disadvantage of the weight, heat radiation and the like caused in the conventional mobile terminal may be solved.

Still further, the connecting portions configured to connect the outer frame and the inner frame with each other may include the inclined area. Accordingly, it becomes easy to realize the curved edge surface of the display unit and the amount of the amorphous metal used in forming the outer frame may be reduced.

Still further, the outer frame may be used as the leading wire for the RF communication and the plurality of the connecting portions may be arranged at the intervals long enough not to interfere with the RF communication.

Further scope of applicability of the present invention will become apparent from the detailed description given hereinafter. However, it should be understood that the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF THE DRAWINGS

FIG. 1A is a block diagram of a mobile terminal in accordance with the present disclosure.

FIGS. 1B and 1C are conceptual views of one example of the mobile terminal, viewed from different directions;

FIG. 2 is an exploded perspective diagram of the mobile terminal;

FIG. 3 is a diagram illustrating a graph showing comparison between mechanical properties of amorphous metal and other metals, and the atomic structures thereof;

FIG. 4 is a front view illustrating some components provided in the mobile terminal;

FIG. 5 includes a front view and a rear view illustrating the coupling of the components;

FIG. 6 is a diagram illustrating the structure (interval) of connecting portions to avoid the interference of frequencies used in RF communication;

FIG. 7 is a sectional diagram illustrating one embodiment along A-A′ of FIG. 1b;

FIG. 8 includes a diagram illustrating the coupling of some components in accordance with one embodiment and an exploded perspective diagram illustrating the coupling;

FIG. 9 is a sectional diagram illustrating another embodiment along A-A′ of FIG. 1b; and

FIG. 10 includes a diagram illustrating the coupling of some components in accordance with another embodiment and an exploded perspective diagram illustrating the coupling.

### DESCRIPTION OF SPECIFIC EMBODIMENTS

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

Mobile terminals presented herein may be implemented using a variety of different types of terminals. Examples of such terminals include cellular phones, smart phones, user equipment, laptop computers, digital broadcast terminals, personal digital assistants (PDAs), portable multimedia players (PMPs), navigators, portable computers (PCs), slate PCs, tablet PCs, ultra books, wearable devices (for example, smart watches, smart glasses, head mounted displays (HMDs)), and the like

By way of non-limiting example only, further description will be made with reference to particular types of mobile terminals. However, such teachings apply equally to other types of terminals, such as those types noted above. In addition, these teachings may also be applied to stationary terminals such as digital TV, desktop computers, and the like.

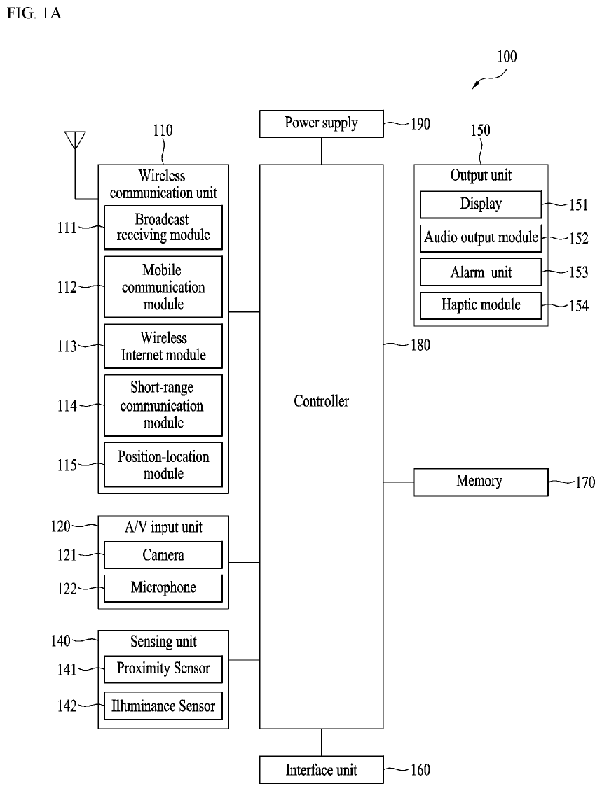

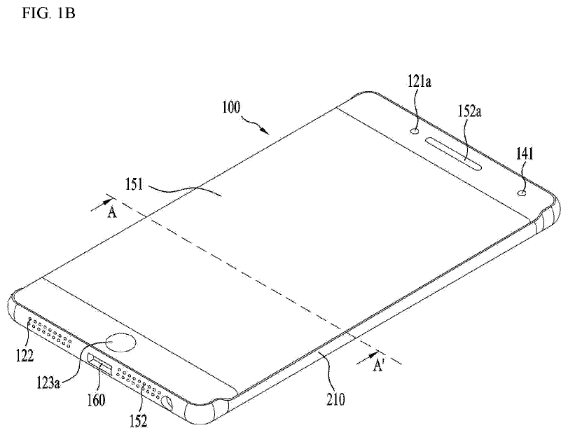

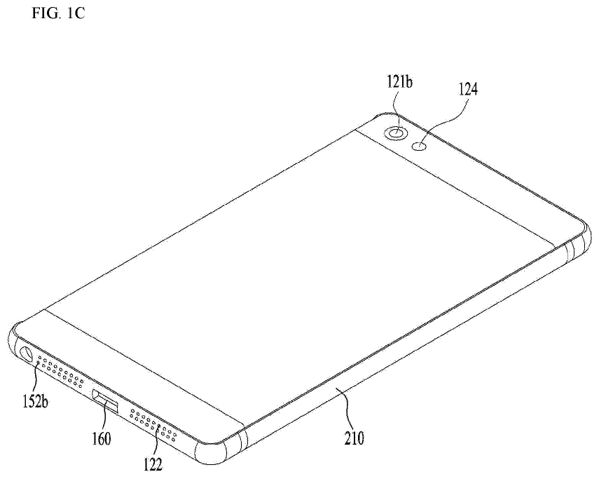

Reference is now made to FIGS. 1A-1C, where FIG. 1A is a block diagram of a mobile terminal in accordance with the present disclosure, and FIGS. 1B and 1C are conceptual views of one example of the mobile terminal, viewed from different directions.

The mobile terminal 100 is shown having components such as a wireless communication unit 110, an input unit 120, a sensing unit 140, an output unit 150, an interface unit 160, a memory 170, a controller 180, and a power supply unit 190. It is understood that implementing all of the illustrated components is not a requirement, and that greater or fewer components may alternatively be implemented.

The wireless communication unit 110 typically includes one or more modules which permit communications such as wireless communications between the mobile terminal 100 and a wireless communication system, communications between the mobile terminal 100 and another mobile terminal, communications between the mobile terminal 100 and an external server. Further, the wireless communication unit 110 typically includes one or more modules which connect the mobile terminal 100 to one or more networks.

To facilitate such communications, the wireless communication unit 110 includes one or more of a broadcast receiving module 111, a mobile communication module 112, a wireless Internet module 113, a short-range communication module 114, and a location information module 115.

The input unit 120 includes a camera 121 for obtaining images or video, a microphone 122, which is one type of audio input device for inputting an audio signal, and a user input unit 123 (for example, a touch key, a push key, a mechanical key, a soft key, and the like) for allowing a user to input information. Data (for example, audio, video, image, and the like) is obtained by the input unit 120 and may be analyzed and processed by controller 180 according to device parameters, user commands, and combinations thereof.

The sensing unit 140 is typically implemented using one or more sensors configured to sense internal information of the mobile terminal, the surrounding environment of the mobile terminal, user information, and the like. For example, in FIG. 1A, the sensing unit 140 is shown having a proximity sensor 141 and an illumination sensor 142. If desired, the sensing unit 140 may alternatively or additionally include other types of sensors or devices, such as a touch sensor, an acceleration sensor, a magnetic sensor, a G-sensor, a gyroscope sensor, a motion sensor, an RGB sensor, an infrared (IR) sensor, a finger scan sensor, a ultrasonic sensor, an optical sensor (for example, camera 121), a microphone 122, a battery gauge, an environment sensor (for example, a barometer, a hygrometer, a thermometer, a radiation detection sensor, a thermal sensor, and a gas sensor, among others), and a chemical sensor (for example, an electronic nose, a health care sensor, a biometric sensor, and the like), to name a few. The mobile terminal 100 may be configured to utilize information obtained from sensing unit 140, and in particular, information obtained from one or more sensors of the sensing unit 140, and combinations thereof.

The output unit 150 is typically configured to output various types of information, such as audio, video, tactile output, and the like. The output unit 150 is shown having a display unit 151, an audio output module 152, a haptic module 153, and an optical output module 154. The display unit 151 may have an inter-layered structure or an integrated structure with a touch sensor in order to facilitate a touch screen. The touch screen may provide an output interface between the mobile terminal 100 and a user, as well as function as the user input unit 123 which provides an input interface between the mobile terminal 100 and the user.

The interface unit 160 serves as an interface with various types of external devices that can be coupled to the mobile terminal 100. The interface unit 160, for example, may include any of wired or wireless ports, external power supply ports, wired or wireless data ports, memory card ports, ports for connecting a device having an identification module, audio input/output (I/O) ports, video I/O ports, earphone ports, and the like. In some cases, the mobile terminal 100 may perform assorted control functions associated with a connected external device, in response to the external device being connected to the interface unit 160.

The memory 170 is typically implemented to store data to support various functions or features of the mobile terminal 100. For instance, the memory 170 may be configured to store application programs executed in the mobile terminal 100, data or instructions for operations of the mobile terminal 100, and the like. Some of these application programs may be downloaded from an external server via wireless communication. Other application programs may be installed within the mobile terminal 100 at time of manufacturing or shipping, which is typically the case for basic functions of the mobile terminal 100 (for example, receiving a call, placing a call, receiving a message, sending a message, and the like). It is common for application programs to be stored in the memory 170, installed in the mobile terminal 100, and executed by the controller 180 to perform an operation (or function) for the mobile terminal 100.

The controller 180 typically functions to control overall operation of the mobile terminal 100, in addition to the operations associated with the application programs. The controller 180 may provide or process information or functions appropriate for a user by processing signals, data, information and the like, which are input or output by the various components depicted in FIG. 1A, or activating application programs stored in the memory 170.

As one example, the controller 180 controls some or all of the components illustrated in FIGS. 1A-1C according to the execution of an application program that have been stored in the memory 170.

The power supply unit 190 can be configured to receive external power or provide internal power in order to supply appropriate power required for operating elements and components included in the mobile terminal 100. The power supply unit 190 may include a battery, and the battery may be configured to be embedded in the terminal body, or configured to be detachable from the terminal body.

At least some of the above components may work together to implement the operation, control, or control of mobile terminals in accordance with the various examples of implementation described below. In addition, the operation, control, or control of the above mobile terminals may be implemented by the operation of at least one application stored in the above memory (170).

Referring now to FIGS. 1B and 1C, the mobile terminal 100 is described with reference to a bar-type terminal body. However, the mobile terminal 100 may alternatively be implemented in any of a variety of different configurations. Examples of such configurations include watch-type, clip-type, glasses-type, or as a folder-type, flip-type, slide-type, swing-type, and swivel-type in which two and more bodies are combined with each other in a relatively movable manner, and combinations thereof. Discussion herein will often relate to a particular type of mobile terminal (for example, bar-type, watch-type, glasses-type, and the like).

However, such teachings with regard to a particular type of mobile terminal will generally apply to other types of mobile terminals as well.

Mobile terminal 100 includes cosmetic cases (e.g. frames, housings, covers, etc.). As the size of the display unit 151 has grown recently, the display unit 151 occupies the front part of the mobile terminal 100 and the glass protecting the display unit 151 can be placed to cover the entire front, forming the front of the mobile handset.

Mobile terminals 100 may have a curved lateral appearance to improve the user's grip. To this end, the outer face of the middle case 210 may be formed in a convex plane, or the display unit 151 may be bent in the direction of the rear face and joined in the middle case 210. In addition, the edges of the rear case 102 may be formed so that they are curved forward.

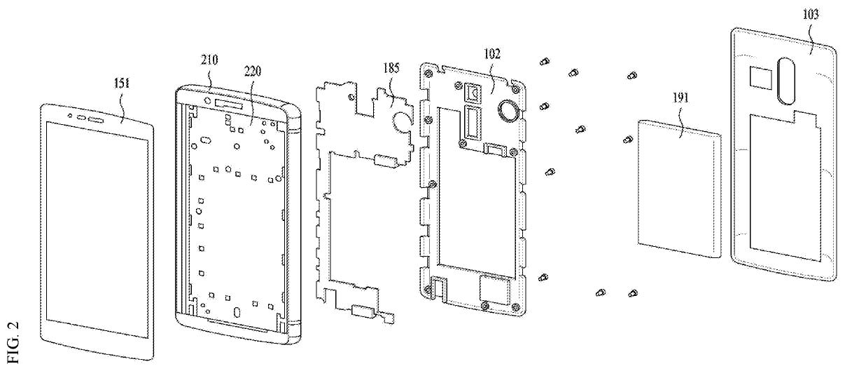

FIG. 2 is an exploded perspective diagram of the mobile terminal 100, and may contain metal plates 220 supporting the displacement of the display unit 151. The display unit 151 is located on the front of the metal plate 220 and various parts such as the printed circuit board 185 and battery 191 are located on the surface of the metal plate 220 above, and the rear case 102 and battery cover 103 are combined in the direction of the surface of the metal plate 220 above.

The rear case 102 may cover up to the side of the metal plate 220, but in this invention the middle case 210 that forms the side of the moving terminal 100 may join around the circumference of the metal plate 220 to form the lateral appearance of the moving terminal.

A display unit 151 is placed on the front of the device body to output information. As illustrated, Windows can join to the front of the case to form the front of the device body.

In some embodiments, electronic components may also be mounted to the rear case 102. Examples of such electronic components include a detachable battery 191, an identification module, a memory card, and the like. Rear cover 103 is shown covering the electronic components, and this cover may be detachably coupled to the rear case 102. Therefore, when the rear cover 103 is detached from the rear case 102, the electronic components mounted to the rear case 102 are externally exposed.

As illustrated, when the rear cover 103 is coupled to the rear case 102, a side surface of the rear case 102 is partially exposed. In some cases, upon the coupling, the rear case 102 may also be completely shielded by the rear cover 103. In some embodiments, the rear cover 103 may include an opening for externally exposing a camera 121b or an audio output module 152b.

The cases 101, 102, 103 may be formed by injection-molding synthetic resin or may be formed of a metal, for example, stainless steel (STS), aluminum (Al), titanium (Ti), or the like.

If the case is made of metal, it can be used as an antenna. To use a case of metal material as an antenna, it is necessary to process the case to be divided according to the performance of the radio signal.

As an alternative to the example in which the plurality of cases form an inner space for accommodating components, the mobile terminal 100 may be configured such that one case forms the inner space. In this example, a mobile terminal 100 having a uni-body is formed in such a manner that synthetic resin or metal extends from a side surface to a rear surface.

If desired, the mobile terminal 100 may include a waterproofing unit (not shown) for preventing introduction of water into the terminal body.

The mobile terminal includes a display unit 151, a first and a second audio output modules 151a/151b, a proximity sensor 141, an illumination sensor 142, an optical output module 154, a first and a second cameras 121a/121b, a first and a second manipulation units 123a/123b, a microphone 122, interface unit 160 and the like.

It will be described for the mobile terminal as shown in FIGS. 1B and 1C. The display unit 151, the first audio output module 151a, the proximity sensor 141, an illumination sensor 142, the optical output module 154, the first camera 121a and the first manipulation unit 123a are arranged in front surface of the terminal body, the second manipulation unit 123b, the microphone 122 and interface unit 160 are arranged in side surface of the terminal body, and the second audio output modules 151b and the second camera 121b are arranged in rear surface of the terminal body.

However, it is to be understood that alternative arrangements are possible and within the teachings of the instant disclosure. Some components may be omitted or rearranged. For example, the first manipulation unit 123a may be located on another surface of the terminal body, and the second audio output module 152b may be located on the side surface of the terminal body.

The display unit 151 is generally configured to output information processed in the mobile terminal 100. For example, the display unit 151 may display execution screen information of an application program executing at the mobile terminal 100 or user interface (UI) and graphic user interface (GUI) information in response to the execution screen information.

The display unit 151 outputs information processed in the mobile terminal 100. The display unit 151 may be implemented using one or more suitable display devices. Examples of such suitable display devices include a liquid crystal display (LCD), a thin film transistor-liquid crystal display (TFT-LCD), an organic light emitting diode (OLED), a flexible display, a 3-dimensional (3D) display, an e-ink display, and combinations thereof.

The display unit 151 may be implemented using two display devices, which can implement the same or different display technology. For instance, a plurality of the display units 151 may be arranged on one side, either spaced apart from each other, or these devices may be integrated, or these devices may be arranged on different surfaces.

The display unit 151 may also include a touch sensor which senses a touch input received at the display unit. When a touch is input to the display unit 151, the touch sensor may be configured to sense this touch and the controller 180, for example, may generate a control command or other signal corresponding to the touch. The content which is input in the touching manner may be a text or numerical value, or a menu item which can be indicated or designated in various modes.

The touch sensor may be configured in a form of a film having a touch pattern, disposed between the window 151a and a display on a rear surface of the window 151a, or a metal wire which is patterned directly on the rear surface of the window 151a. Alternatively, the touch sensor may be integrally formed with the display. For example, the touch sensor may be disposed on a substrate of the display or within the display.

The display unit 151 may also form a touch screen together with the touch sensor. Here, the touch screen may serve as the user input unit 123 (see FIG. 1A). Therefore, the touch screen may replace at least some of the functions of the first manipulation unit 123a.

The first audio output module 152a may be implemented in the form of a speaker to output voice audio, alarm sounds, multimedia audio reproduction, and the like.

The window 151a of the display unit 151 will typically include an aperture to permit audio generated by the first audio output module 152a to pass. One alternative is to allow audio to be released along an assembly gap between the structural bodies (for example, a gap between the window 151a and the front case 101). In this case, a hole independently formed to output audio sounds may not be seen or is otherwise hidden in terms of appearance, thereby further simplifying the appearance and manufacturing of the mobile terminal 100.

The optical output module 154 can be configured to output light for indicating an event generation. Examples of such events include a message reception, a call signal reception, a missed call, an alarm, a schedule notice, an email reception, information reception through an application, and the like. When a user has checked a generated event, the controller can control the optical output unit 154 to stop the light output.

The first camera 121a can process image frames such as still or moving images obtained by the image sensor in a capture mode or a video call mode. The processed image frames can then be displayed on the display unit 151 or stored in the memory 170.

The first and second manipulation units 123a and 123b are examples of the user input unit 123, which may be manipulated by a user to provide input to the mobile terminal 100. The first and second manipulation units 123a and 123b may also be commonly referred to as a manipulating portion, and may employ any tactile method that allows the user to perform manipulation such as touch, push, scroll, or the like. The first and second manipulation units 123a and 123b may also employ any non-tactile method that allows the user to perform manipulation such as proximity touch, hovering, or the like.

FIG. 1B illustrates the first manipulation unit 123a as a touch key, but possible alternatives include a mechanical key, a push key, a touch key, and combinations thereof.

Input received at the first and second manipulation units 123a and 123b may be used in various ways. For example, the first manipulation unit 123a may be used by the user to provide an input to a menu, home key, cancel, search, or the like, and the second manipulation unit 123b may be used by the user to provide an input to control a volume level being output from the first or second audio output modules 152a or 152b, to switch to a touch recognition mode of the display unit 151, or the like.

As another example of the user input unit 123, a rear input unit (not shown) may be located on the rear surface of the terminal body. The rear input unit can be manipulated by a user to provide input to the mobile terminal 100. The input may be used in a variety of different ways. For example, the rear input unit may be used by the user to provide an input for power on/off, start, end, scroll, control volume level being output from the first or second audio output modules 152a or 152b, switch to a touch recognition mode of the display unit 151, and the like. The rear input unit may be configured to permit touch input, a push input, or combinations thereof.

The rear input unit may be located to overlap the display unit 151 of the front side in a thickness direction of the terminal body. As one example, the rear input unit may be located on an upper end portion of the rear side of the terminal body such that a user can easily manipulate it using a forefinger when the user grabs the terminal body with one hand. Alternatively, the rear input unit can be positioned at most any location of the rear side of the terminal body.

Embodiments that include the rear input unit may implement some or all of the functionality of the first manipulation unit 123a in the rear input unit. As such, in situations where the first manipulation unit 123a is omitted from the front side, the display unit 151 can have a larger screen.

As a further alternative, the mobile terminal 100 may include a finger scan sensor which scans a user's fingerprint. The controller 180 can then use fingerprint information sensed by the finger scan sensor as part of an authentication procedure. The finger scan sensor may also be installed in the display unit 151 or implemented in the user input unit 123.

The microphone 122 is shown located at an end of the mobile terminal 100, but other locations are possible. If desired, multiple microphones may be implemented, with such an arrangement permitting the receiving of stereo sounds.

The interface unit 160 may serve as a path allowing the mobile terminal 100 to interface with external devices. For example, the interface unit 160 may include one or more of a connection terminal for connecting to another device (for example, an earphone, an external speaker, or the like), a port for near field communication (for example, an Infrared Data Association (IrDA) port, a Bluetooth port, a wireless LAN port, and the like), or a power supply terminal for supplying power to the mobile terminal 100. The interface unit 160 may be implemented in the form of a socket for accommodating an external card, such as Subscriber Identification Module (SIM), User Identity Module (UIM), or a memory card for information storage.

The second camera 121b is shown located at the rear side of the terminal body and includes an image capturing direction that is substantially opposite to the image capturing direction of the first camera unit 121a.

The second camera 121b can include a plurality of lenses arranged along at least one line. The plurality of lenses may also be arranged in a matrix configuration. The cameras may be referred to as an “array camera.” When the second camera 121b is implemented as an array camera, images may be captured in various manners using the plurality of lenses and images with better qualities.

As shown in FIG. 1C, a flash 124 is shown adjacent to the second camera 121b. When an image of a subject is captured with the camera 121b, the flash 124 may illuminate the subject.

As shown in FIG. 1B, the second audio output module 152b can be located on the terminal body. The second audio output module 152b may implement stereophonic sound functions in conjunction with the first audio output module 152a, and may be also used for implementing a speaker phone mode for call communication.

At least one antenna for wireless communication may be located on the terminal body. The antenna may be installed in the terminal body or formed by the case. For example, an antenna which configures a part of the broadcast receiving module 111 may be retractable into the terminal body. Alternatively, an antenna may be formed using a film attached to an inner surface of the rear cover 103, or a case that includes a conductive material.

A power supply unit 190 for supplying power to the mobile terminal 100 may include a battery 191, which is mounted in the terminal body or detachably coupled to an outside of the terminal body.

The battery 191 may receive power via a power source cable connected to the interface unit 160. Also, the battery 191 can be recharged in a wireless manner using a wireless charger. Wireless charging may be implemented by magnetic induction or electromagnetic resonance.

The rear cover 103 is shown coupled to the rear case 102 for shielding the battery 191, to prevent separation of the battery 191, and to protect the battery 191 from an external impact or from foreign material. When the battery 191 is detachable from the terminal body, the rear case 103 may be detachably coupled to the rear case 102.

An accessory for protecting an appearance or assisting or extending the functions of the mobile terminal 100 can also be provided on the mobile terminal 100. As one example of an accessory, a cover or pouch for covering or accommodating at least one surface of the mobile terminal 100 may be provided. The cover or pouch may cooperate with the display unit 151 to extend the function of the mobile terminal 100. Another example of the accessory is a touch pen for assisting or extending a touch input to a touch screen.

Further preferred embodiments will be described in more detail with reference to additional drawing figures. It is understood by those skilled in the art that the present features can be embodied in several forms without departing from the characteristics thereof.

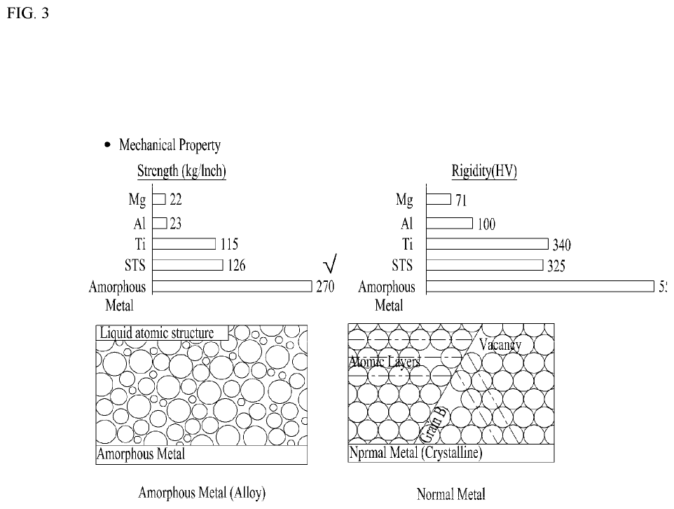

FIG. 3 is a diagram illustrating a graph showing comparison between mechanical properties of amorphous metal and other metals, and the atomic structures thereof.

The amorphous metal means the metal which is solidified with a disordered arrangement of atoms by the rapid solidification of gas or liquid which is performed rapid enough not to have a crystal structure. Initially, such the amorphous metal was made from alloy of palladium (Pd) and silicon (Si) and it is too expensive to be suited to actual use. Recently, a new amorphous metal made from mixture of zirconium (Zr), titanium (Ti), nickel (Ni) and copper (Cu) is used and it is often called “liquid metal” because of a smooth surface like liquid.

The amorphous metal has high strength and rigidity, compared with conventional metals. The crystal metal tends to be split along crystal and the amorphous metal will not be split. For examples, the strength of amorphous steel is 20 kg/1 mm² but the strength of amorphous steel alloy is 400 kg/1 mm². The amorphous metal has a high rigidity so that it may be resistant to scratch.

The amorphous metal has high anti-corrosion (that is resistant to corrosion). When fabricated by molding, the amorphous metal has a smooth surface which is easy to polish.

Accordingly, when a case of a mobile terminal is made by using the amorphous metal, it becomes easy to polish the case and enhance the exterior design and also provide a mobile terminal which is strongly resistant to scratches.

However, the amorphous metal is subject to heat, with low heat conductivity. At a high temperature, the amorphous metal returns to a normal crystal metal because of the heat. The limit temperature of the high temperatures is typically 400˜500° C. Also, the amorphous metal has a great specific gravity to be heavy and difficult to manufacture with high cost and high electric resistance disadvantageously.

Because of such disadvantages of the amorphous metal, the mobile terminal having a case made of the amorphous metal becomes heavy and it is difficult to radiate the internal heat. In addition, such a mobile terminal is confronted with limits on high electric resistance and high cost.

To overcome such limits, a hybrid structure may be considered that an outer frame exposed outside (hereinafter, a middle case) is made of the amorphous metal and an inner frame (hereinafter, a metal plate) is made of a different metal from the amorphous metal.

Hereinafter, the hybrid structure of the frame will be described in detail.

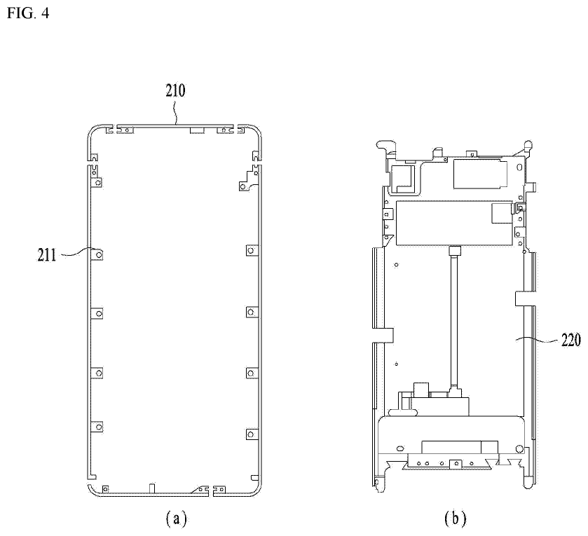

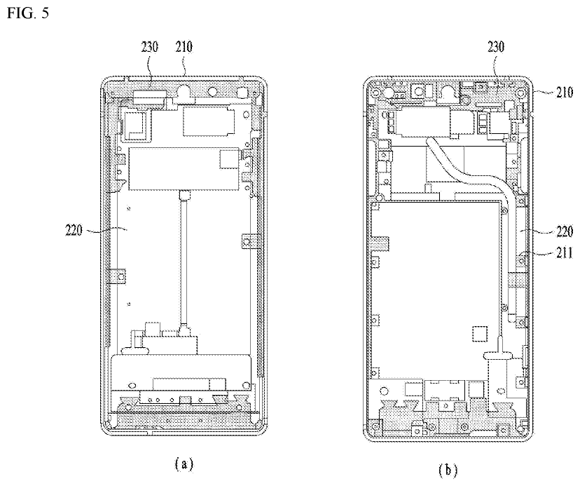

FIG. 4 is a front view illustrating the middle case 210 defining the exterior of the mobile terminal and the metal plate 220 connected with the middle case in the mobile terminal. FIG. 5 includes a front view and a rear view illustrating the coupling between the middle case 210 and the metal plate 220 via a molding portion 230.

The frame of the mobile terminal is configured of the metal plate 220 configured to support a rear surface of the display unit 151; and the middle case 210 arranged around the metal plate 220; and a connecting portion 211 projected from an inner surface of the middle case 210 to connect the metal plate 220 and the middle case 210 with each other.

In this instance, the molding portion 230 is insert-molded between the inner surface of the middle case 210 and the metal plate 220 and configured to enhance the coupling force between the middle case 210 and the metal plate 220. The coupling which uses the molding portion 230 may be especially advantageous in making the middle case 210 and the metal plate 220 by using different metals.

Considering that it is exposed outside and defines the exterior of the mobile terminal, the middle case 210 may be made of an amorphous metal having higher strength and rigidity than the metal plate 210. Accordingly, the middle case 210 made of the amorphous metal is easy to be polish so as to enhance the design and minimize scratch.

In the hybrid frame configured to form the metal plate 220 connected with the middle case 210 formed of the amorphous metal by using a different metal from the amorphous metal, the metal plate 220 may be formed of a metal having a higher heat transfer coefficient, a smaller specific gravity and a lower electric resistance than the middle case 210.

The metal plate 220 may be formed of aluminum (Al) or magnesium (Mg).

If the middle case 210 is formed of aluminum (Al) or magnesium (Mg), it becomes difficult to polish the exposed area and subject to external scratch.

Accordingly, the middle case 210 is formed of the amorphous metal and the metal plate 220 connected with the middle case 210 is formed of aluminum (Al) or magnesium (Mg), only to realize the mobile terminal which is capable of overcoming the limits of the weight, heat radiation and electric resistance, while it is easy to polish the exposed area and subject to scratch.

The middle case 210 exposed outside may be fabricated in a ring-shape to minimize the increase of the weight and expense and then connected with the metal plate 220 formed of the different metal there from.

The hybrid frame is formed by connecting the different metals with each other, so that it may be necessary to consider the connecting portion 211 configured to connect the middle case 210 and the metal plate 220 with each other. Hereinafter, the connecting portion 211 will be described in detail.

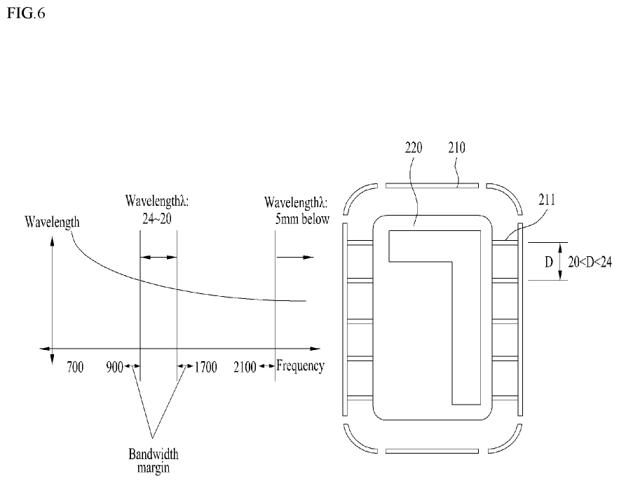

FIG. 6 illustrates that the middle case 210 is connected with the metal plate 220 by using a plurality of connecting portions 211 and FIG. 6 also illustrates intervals of the connecting portions 211 and the relation with the frequency (wavelength) used in RF communication.

The mobile terminal may further include a wireless communication unit 110 configured to implement RF communication by supplying the power to the middle case 210.

The plurality of the connecting portions 211 may be spaced a preset distance apart from each other in the middle case 210 and cause interference with the frequency (wavelength) used in RF communication. To avoid the interference with the frequency used in RF communication, the plurality of the connecting portions 211 may be arranged at intervals which are as long as the length of the frequency not used in RF communication.

The range of distances which could be used as the intervals of the connecting portions 211 may include a preset gap so as to avoid the interference while not being overlapped with the range of the frequencies usually used in the RF communication by the wireless communication unit 110.

For example, when the wireless communication unit 110 uses signals at 700 MHz˜900 MHz or 1700 MHz˜2100 MHz in the RF communication, the connecting portions 211 may be formed along the middle case 210 at intervals of 20 mm˜24 mm.

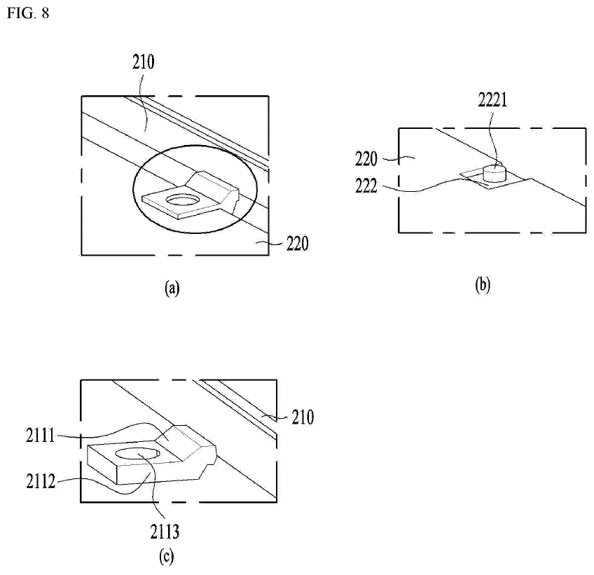

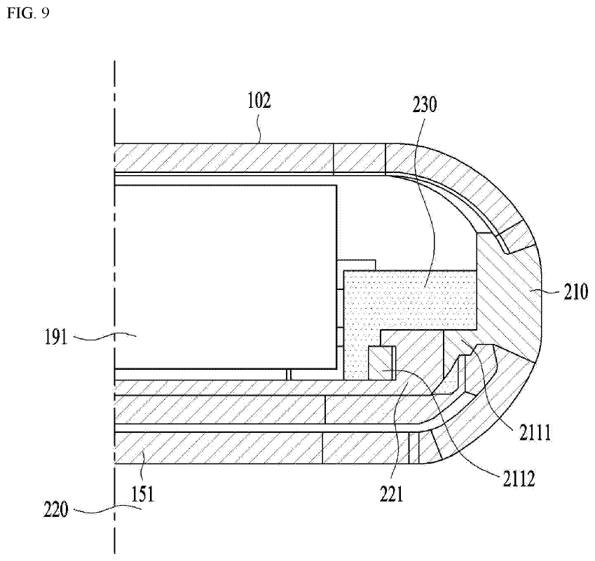

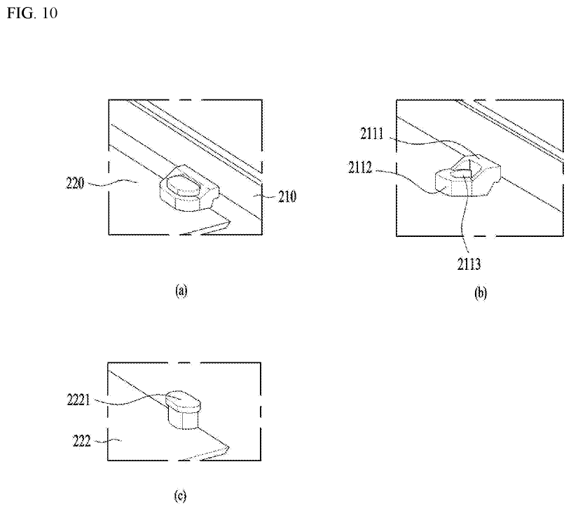

FIGS. 6 and 8 are enlarged views of A-A′ and illustrate different embodiments of the coupling between the middle case 210 and the metal plate 220 by using the connecting portions 211.

The connecting portions 210 may be connected with the metal plate 220 via a rivet. Alternatively, the connecting portions 210 may be connected with the metal plate 220 by welding and the welding method might have a weak coupling force, considering that the different metals are coupled to each other. The connecting portions 210 may be connected with the metal plate 220 by using a bolt. The bolt could be subject to vibration and it might not be proper to the bonding portion with a short clamp length.

The connecting portions 211 connected with the metal plate via the rivet may include an inclined area 2111 extended from the inner surface of the middle case 210 and inclined toward the display unit 151; and a fastening area 2112 extended from one end of the inclined area 2111 in parallel with the metal plate 220 and configured to have a rivet projection 2221 pass thereby.

It is easy to adjust the height of the connecting portions 211 to the metal plate 220 supporting the rear surface of the display unit 151, because it includes the inclined area 2111 inclined toward the display unit 151.

The connecting portions 211 include the inclined area 2111 and are connected with the metal plate 220, so as to efficiently support the display unit 1151 having an edge bending backwardly. The edge of the display unit 151 is bending to contact with the front surface of the middle case so that the user's grip sense can be enhanced and the volume occupied by the middle case in the lateral surface can be reduced to save the expense cost in manufacturing the case including the amorphous metal.

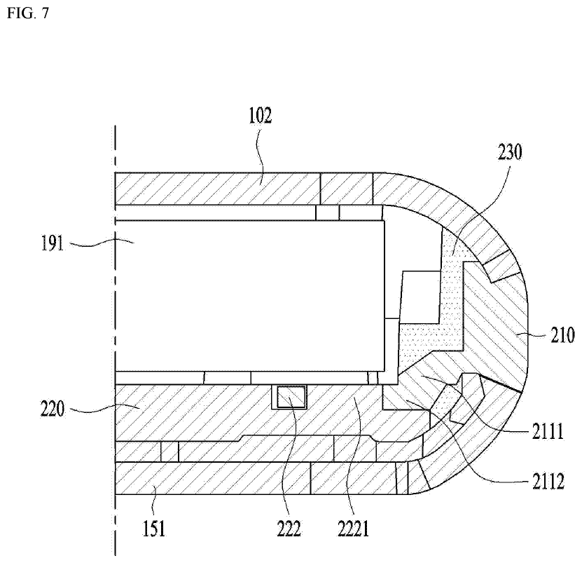

FIGS. 6 and 7 illustrate one embodiment that the connecting portions 211 are connected with the metal plate 220 via the rivet. The metal plate 220 include a groove 222 formed in an edge to receive the fastening area 2112. A hole 2113 may be formed in the fastening area 2112 or the groove 222 and a rivet projection 2221 may be formed in the other one of the two to be inserted in the hole 2113.

The structure may result in increasing the thickness of the metal plate 220. However, the rivet connecting portion 211 may define a surface in contact with the battery 191 at the same plane with the metal plate 220, so as to prevent the increase of the right-and-left width of the mobile terminal.

FIGS. 7 and 8 illustrate another embodiment that the metal plate 220 includes a rivet projection 2221 projected from the edge backwardly to be inserted in a hole 2113 formed in the fastening area 2112.

In such the structure, the rivet projection is projected from the rear surface of the metal plate 220 and disposed between the battery 191 and the metal plate. Because of that, the structure might result in increasing the right-and-left width of the mobile terminal. The rivet fastening structure is capable of reducing the thickness of the metal plate 220 and preventing the increase of the overall thickness of the mobile terminal.

Next, the molding portion 230 insert-injection-molded along the inner surface of the middle case 210 will be described in detail.

In the rivet connecting structure, the metal plate 220 and the middle case 210 may be coupled to each other by using the molding portion 230 insert-molded along the inner surface of the middle case 210, so as to reinforce the coupling force between them.

More specifically, the connecting portions 211 are rivet-connected with the metal plate 220 and the molding portion 230 is inserted to couple the metal plate 220 and the middle case 210 to each other.

The molding portion 230 is formed around the connecting portions 211 and configured to enhance the coupling force of the connecting portions 211. The molding portion 230 may also seat the spaced area between the metal plate 220 and the middle case 210 to prevent water from flowing between the metal plate 220 and the middle case 210.

The molding portion 230 may be continuously formed along the inner surface of the middle case 210 and have one surface which contacts with at least one of the display unit 151 and the rear case 102. At this time, the molding portion 230 is formed by plastic injection-molding and easy to realize a curved surface. In case at least one of the display unit 151 and the rear case 102 includes a curved edge, it is easy to fabricate the molding portion to be fitted to the curved edge.

The molding portion 230 is configured to contact with at least one of the display unit 151 and the rear case 102 and includes a waterproof member (not shown) provided in the surface in contact with the display unit 151 and/or the rear case 102, so as to prevent water from permeating into the mobile terminal.

When the middle case 210 and the metal plate 220 are coupled to each other by using the molding portion 230 as mentioned above, the waterproof and dustproof functions and the coupling force of the mobile terminal may be enhanced and it is easy to express or realize the curved surface so as to enhance the design freedom of the mobile terminal.

It may result in the decrease of the back-and-force width of the middle case 210 that the curved surface is formed in the display unit 151 or the rear case by using the molding portion 230. In addition, the economic effect may be expected by the reduce of the amorphous metal usage.

As the present features may be embodied in several forms without departing from the characteristics thereof, it should also be understood that the above-described embodiments are not limited by any of the details of the foregoing description, unless otherwise specified, but rather should be considered broadly within its scope as defined in the appended claims, and therefore all changes and modifications that fall within the metes and bounds of the claims, or equivalents of such metes and bounds, are therefore intended to be embraced by the appended claims.

What is claimed is:

1. A mobile terminal comprising:
a display unit;
a metal plate configured to support a rear surface of the display unit;
a middle case arranged around the metal plate and comprising a connecting portion projected from an inner surface and connected with the metal plate;
a molding portion injection-molded between an inner surface of the middle case and the metal plate; and
a rear case coupled to a rear surface of the middle case and configured to define an exterior of the rear surface,
wherein the middle case is formed of an amorphous metal having higher strength and rigidity than a metal of the metal plate.

2. The mobile terminal of claim 1, wherein the metal plate is formed of a metal having a higher heat transfer coefficient and a lower electric resistance than the metal of the middle case.

3. The mobile terminal of claim 2, wherein the metal plate is formed of aluminum or magnesium.

4. The mobile terminal of claim 1, further comprising:
a wireless communication unit configured to supply an electric power to the middle case and implement RF communication,
wherein the plurality of the connecting portion are arranged at preset intervals in the inner surface of the middle case, and
the distance between the connecting portions is different from the wavelength of a signal used in the RF communication.

5. The mobile terminal of claim 4, wherein the signal used in the RF communication is 700 MHz˜900 MHz or 1700 MHz˜2100 MHz, and
the connecting portions are arranged along the middle case at intervals of 20 mm˜24 mm.

6. The mobile terminal of claim 1, wherein the connecting portion is connected with the metal plate via a rivet.

7. The mobile terminal of claim 6, wherein the connecting portion comprises,
an inclined area extended from the inner surface of the middle case and inclined toward the display unit; and
a fastening area extended from one end of the inclined area, in parallel with the metal plate, and connected with the metal plate via the rivet.

8. The mobile terminal of claim 7, wherein the metal plate comprises,
a groove provided in an edge and configured to receive the fastening area and
a hole is formed in one of the fastening area and the groove and a rivet projection is provided in the other one to be inserted in the hole.

9. The mobile terminal of claim 7, wherein the metal plate comprises,
a rivet projection projected from the edge backwardly and configured to be inserted in the hole formed in the fastening area.

10. The mobile terminal of claim 7, wherein an edge of the display unit is bent backwardly to contact with a front surface of the middle case, and
the molding portion is configured to contact with an edge of a rear surface of the display unit, while surrounds the connecting portions.
